(19) United States
(12) Patent Application Publication
(10) Pub. No.: US 2024/0258112 A1
(43) Pub. Date: Aug. 1, 2024

(54) MULTI-LOOP TIME VARYING BOSCH PROCESS FOR 2-DIMENSIONAL SMALL CD HIGH ASPECT RATIO DEEP SILICON TRENCH ETCHING

(71) Applicant: Texas Instruments Incorporated, Dallas, TX (US)

(72) Inventors: Chao Zuo, Chengdu (CN); Jing Hu, Chengdu (CN); Tian Ping Lv, Yibin (CN); Abbas Ali, Plano, TX (US); Manoj K Jain, Plano, TX (US)

(21) Appl. No.: 18/103,134

(22) Filed: Jan. 30, 2023

(51) Int. Cl. H01L 21/3065

(52) U.S. Cl. CPC H01L 21/30655; H01L 28/40

(57) ABSTRACT

A method of forming an integrated circuit includes forming a plurality of openings in a resist layer over a semiconductor substrate and removing portions of a semiconductor surface layer exposed by the openings, thereby forming a plurality of deep trenches. Removing the portions includes performing a first etch loop for a first plurality of repetitions, the first etch loop including a deposition process executed for a first deposition time and an etch process executed for a first etch time. The removing further includes performing a second etch loop for a second plurality of repetitions, the second etch loop including the deposition process executed for a second deposition time and an etch process executed for a second etch time. The second deposition time is at least 10% greater than the first deposition time, and the second etch time is at least 10% greater than the first etch time.

### FIELD

This disclosure relates to the field of semiconductor manufacturing, and more particularly, but not exclusively, to forming high aspect ratio openings in a silicon substrate.

### BACKGROUND

High aspect ratio openings, such as holes, in a silicon substrate are desirable in various device applications. It may be difficult to form such openings greater than a certain depth with a diameter that is relatively constant from the top of the opening to the bottom of the opening.

### SUMMARY

This summary is provided to introduce a brief selection of disclosed concepts in a simplified form that are further illustrated and described below. This summary is not intended to limit the scope of the claimed subject matter. Disclosed aspects include semiconductor devices and fabrication methods therefor. In one example a method of forming an integrated circuit includes forming a plurality of openings in a resist layer over a semiconductor substrate and removing portions of a semiconductor surface layer exposed by the openings, thereby forming a plurality of deep trenches. Removing the portions includes performing a first etch loop for a first plurality of repetitions, the first etch loop including a deposition process executed for a first deposition time and an etch process executed for a first etch time. The removing further includes performing a second etch loop for a second plurality of repetitions, the second etch loop including the deposition process executed for a second deposition time and an etch process executed for a second etch time. The second deposition time is at least 10% greater than the first deposition time, and the second etch time is at least 10% greater than the first etch time.

Another example includes an integrated circuit that includes a semiconductor surface layer having a first conductivity type over a substrate. A buried layer within the semiconductor surface layer has an opposite second conductivity type. A trench extends from a top surface of the semiconductor surface layer into the buried layer, and has a depth of at least 20 μm, an aspect ratio of at least 10:1, and a bottom diameter at a trench bottom at least about 75% of a top diameter at the top surface.

Other examples include methods of manufacturing integrated circuit devices according to the integrated circuit described above.

### BRIEF DESCRIPTION OF THE DRAWINGS

FIG. 1 is a partial sectional side elevation view of an integrated circuit semiconductor device that includes deep trench isolation structures and trench capacitors.

FIG. 2 is a top plan view of a portion of the semiconductor device of FIG. 1.

FIG. 3A is a detail of a portion of FIG. 1.

FIG. 3B is a section view of a portion of an electronic device formed according to examples of the disclosure.

FIGS. 4A-4C are micrographs of sections through round trenches formed according to various variations of a Bosch process.

FIGS. 5A-5C are micrographs of sections through round trenches formed according to an example of the disclosure.

FIG. 6 illustrates pictorially trenches etched according to a prior art example

FIG. 7 illustrates pictorially trenches etched according to an example of the disclosure.

FIGS. 8A-8D illustrate an example electronic device formed according to examples of the disclosure.

### DETAILED DESCRIPTION

In the drawings, like reference numerals refer to like elements throughout, and the various features are not necessarily drawn to scale. In the following discussion and in the claims, the terms “including”, “includes”, “having”, “has”, “with”, or variants thereof are intended to be inclusive in a manner similar to the term “comprising”, and thus should be interpreted to mean “including, but not limited to . . . ” Also, the term “couple” or “couples” is intended to include indirect or direct electrical or mechanical connection or combinations thereof. For example, if a first device couples to or is coupled with a second device, that connection may be through a direct electrical connection, or through an indirect electrical connection via one or more intervening devices and connections. The various features of the disclosed examples can be used in connection with a variety of different semiconductor devices, including without limitation integrated circuits having multiple electronic components, as well as single component semiconductor devices (e.g., single transistor products, single diode products, etc.).

Various disclosed devices and methods of the present disclosure may be beneficially applied to integrated circuits by providing very deep, high aspect-ratio trenches or holes in a semiconductor substrate. While such examples may be expected to provide benefit to devices such as deep trench capacitors, no particular result is a requirement of the present invention unless explicitly recited in a particular claim.

Example devices and fabrication methods provide process integration for both trench isolation and high density trench capacitors fabricated using a shared resist mask to economize fabrication time and costs. In some examples, the trenches are etched, deep doped regions surrounding the trenches are implanted, and the trenches are lined and filled using a thick photoresist and hard mask patterned with openings for capacitor trenches and wider openings for isolation structure trenches. Described examples provide metallization layout structures to provide first and second capacitor plates for capacitor trench structures, and connected polysilicon and deep doped regions for isolation trench structures. Described examples facilitate forming deep trench isolation features as well as high density trench capacitor with one mask, and with reduced isolation (e.g., deep n region) to isolation spacing using self-aligned deep doped region implantation on deep trench sidewalls.

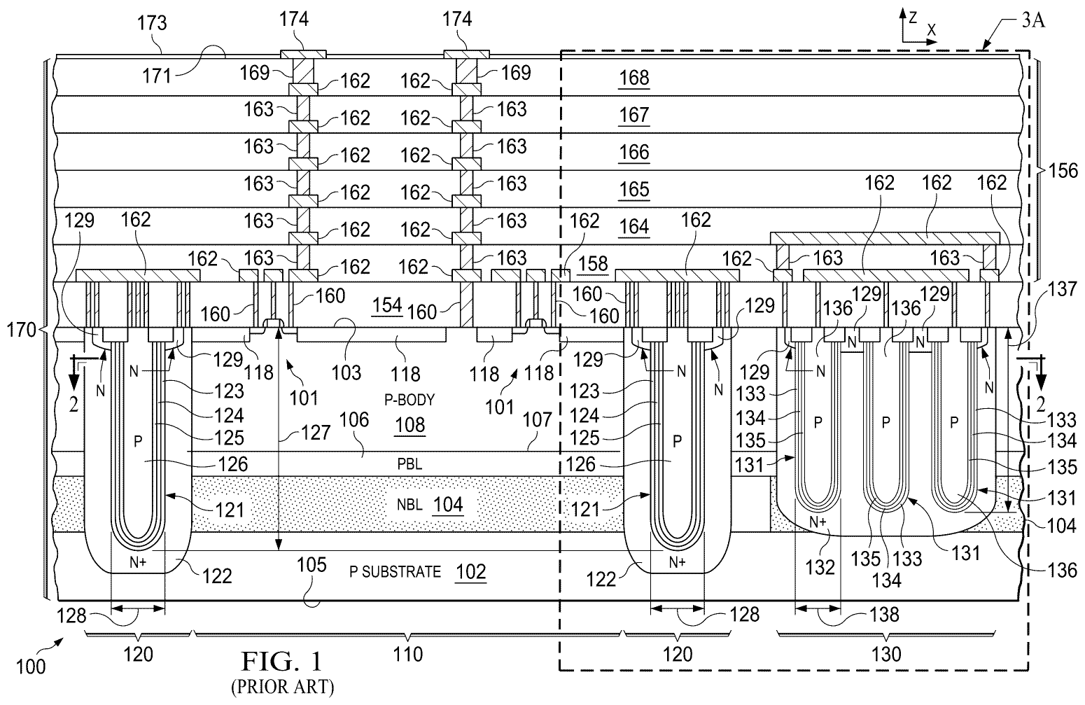

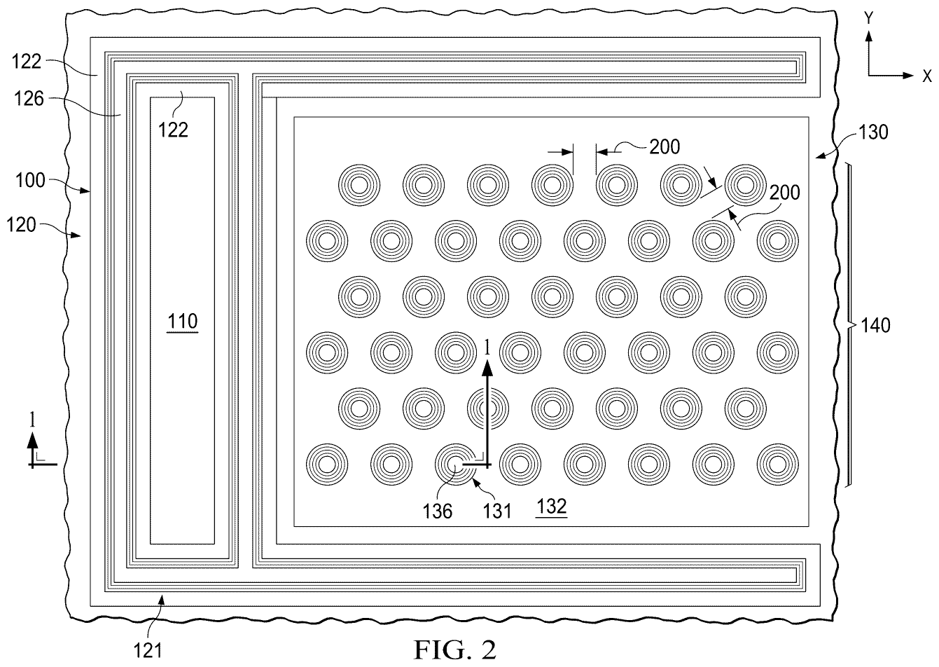

FIGS. 1 and 2 show an example integrated circuit semiconductor device 100 that includes two metal oxide semiconductor (MOS) transistors 101. Disclosed examples can also include stand-alone discrete transistor semiconductor devices that have a single transistor. The transistors 101 in FIG. 1 have single gate, source and drain finger structures. In other implementations, transistors can be built with multiple finger structures surrounding a center finger, such as source-centered configurations, drain-centered configurations, etc. The deep trench isolation and trench capacitor concepts of the present disclosure can be implemented in combination with any type or form of transistor, such as MOS transistors bipolar transistors, etc. In addition, various aspects of the disclosure can be used in combination with drain extended MOS transistors (not shown). Described examples include doped regions of various semiconductor structures which may be characterized as p-doped and/or n-doped regions or portions, and include regions that have majority carrier dopants of a particular type, such as n-type dopants or p-type dopants.

The transistors 101 are fabricated on and/or in a semiconductor substrate 102. The semiconductor substrate 102 in one example is a silicon wafer, a silicon-on-insulator (SOI) substrate or other semiconductor structure. In one example, the substrate 102 is a p-doped silicon substrate or wafer, with a first (e.g., top) side 103, various buried layers 104, 106 formed therein, and a second (e.g., bottom) side 105. In another possible implementation, the substrate 102 includes one or more epitaxial silicon layers (not shown) formed on a top surface, with one or more of the buried layers 104, 106 formed in epitaxial layers of the substrate. In the illustrated example, the substrate 102, the buried layers 104 and 106, and an upper semiconductor surface layer (e.g., body region 108) constitute a semiconductor structure. The example semiconductor structure includes a first doped layer 106 that includes p-type majority carrier dopants. In one implementation, the p-type layer includes a portion implanted with boron to form a p-type buried layer (PBL) with an upper or top side 107. The semiconductor surface layer 108 extends over (e.g., directly on) the p-type buried layer 106 and includes the upper side 103 of the semiconductor structure. The example layer 104 (e.g., an n-type buried layer or NBL) includes n-type majority carrier dopants. The NBL 104 extends along the vertical Z direction from beneath the PBL 106 toward the second side 105. In one example, a first epitaxial silicon layer is formed over the upper surface of a silicon wafer substrate 102, and all or a portion of the first epitaxial layer is implanted with n-type dopants (e.g., phosphorus, etc.) to form the NBL 104. In this example, a second epitaxial silicon layer is formed over the first epitaxial layer, and all or a portion of the second epitaxial layer is implanted with p-type dopants (e.g., boron, etc.) to form the p-type buried layer 106 with the upper side 107. In one example, the PBL region 106 is formed using ion implantation through the first EPI surface. The example surface layer 108 has p-type majority carrier dopants and extends downward along the Z direction from the first side 103.

The transistors 101 are formed on or in the semiconductor surface layer 108 within an active region 110 of the semiconductor structure 102, 104, 106, 108. The example semiconductor surface layer 108 includes p-type majority carrier dopants. The illustrated device 100 includes an outer oxide isolation structure 118 that encircles the transistor 101 along the first (e.g., top) side 103 in the semiconductor surface layer 108. The oxide structure 118 in one example is a shallow trench isolation (STI) structure, which is disposed laterally outward of the transistors 101. In the illustrated example, the STI structure 118 defines an end of the active region 110 of the semiconductor substrate 102 in which the transistors 101 are formed.

The illustrated device 100 includes a trench-based isolation structure 120, referred to as a deep trench isolation structure. The deep trench isolation structure 120 in FIG. 1 is adjacent to the STI structure 118, and laterally encircles or surrounds the transistors 101 and the active region 110 of the semiconductor structure. The isolation structure 120 includes a first trench 121 that extends downward from the first side 103 through the semiconductor structure 102, 104, 106, 108 to the buried layer 104. The isolation structure 120 also includes a first deep doped region 122 with n-type majority carrier dopants (e.g., phosphorus). The first deep doped region 122 surrounds the first trench 121 and extends from the semiconductor surface layer 108 to the buried layer 104.

The isolation structure 120 also includes a first dielectric liner that extends along the sidewall of the first trench 121 from the semiconductor surface layer 108 to the buried layer 104. Any single or multilayer dielectric liner can be used. In one example, the first dielectric liner includes a first oxide layer 123, a nitride layer 124, and a second oxide layer 125. The first oxide layer 123 (e.g., silicon dioxide or SiO₂) extends along the sidewall of the first trench 121 from the semiconductor surface layer 108 to the buried layer 104. The nitride layer 124 (e.g., silicon nitride or silicon oxynitride) extends along the first oxide layer 123 from the semiconductor surface layer 108 to the buried layer 104. The second oxide layer 125 (e.g., silicon dioxide or SiO₂) extends along the nitride layer 124 from the semiconductor surface layer 108 to the buried layer 104.

The isolation structure 120 also includes a first polysilicon 126 that extends inside the first dielectric liner 123, 124, 125. The first polysilicon 126 fills the first trench 121 to the top side 103 of the semiconductor surface layer 108. The first polysilicon 126 in one example includes p-type majority carrier dopants (e.g., boron). In the example of FIGS. 1 and 2, the deep trench isolation structure 120 is formed as a ring structure that laterally surrounds the transistors 101. As shown in FIG. 1, the first trench 121 has a first depth 127 and a first width 128. The semiconductor device 100 also includes shallow implant regions 129 with n-type majority carrier dopants (e.g., a shallow n-well implanted with phosphorus). The shallow implant regions 129 extend in the semiconductor surface layer 108 along a side of the first trench 121 within the first deep doped region 122. In one example, the shallow implant is also used to form lower case n-type source/drain features (not shown) of transistors in the device 100.

The illustrated device 100 also includes one or more trench-based capacitors, e.g. deep-trench capacitors. In one example, a trench capacitor 130 can be constructed using a single trench. In the example of FIGS. 1 and 2, the capacitor 130 includes multiple second trenches 131 that individually extend through the semiconductor structure 102, 104, 106, 108 to the buried layer 104. The trenches 131 are circular cylindrical trenches, though other geometries are within the scope of the disclosure. Each of the second trenches 131 is surrounded by a second deep doped region 132. FIG. 1 shows three trenches 131 that extend from the first side 103 through the semiconductor structure to the buried layer 104. The second trench 131 has a second depth 137 and a second width 138. The first width 128 of the first (isolation) trench 121 is greater than the second (capacitor trench) width 138 of the capacitor trenches 131. In one example, the first width 128 of the first trench 121 is approximately 1.5 μm, for example, from 1.35 μm to 1.65 μm, and the second width 138 of the capacitor trenches 131 is approximately 1.2 μm, for example, from 1.05 μm to 1.35 μm. In one example the depth 137 is about 5.5 μm to 6.5 μm, and the depth 127 is about 6.2 μm to 7.2 μm, the greater depth being a result of the width 128 being greater than the width 128.

The example capacitor 130 further includes second dielectric liners (e.g., layers 133, 134, and 135) in each of the trenches 131. The second dielectric liners extend along sidewalls of the second trenches 131 from the semiconductor surface layer 108 to the buried layer 104. The example second dielectric liner is a multi-layer structure with a third oxide layer 133 that extends along the sidewall of the second trench 131 from the semiconductor surface layer 108 to the buried layer 104. The example second dielectric liner also includes a second nitride layer 134 that extends along the third oxide layer 133 from the semiconductor surface layer 108 to the buried layer 104, and a fourth oxide layer 135 that extends along the second nitride layer 134 from the semiconductor surface layer 108 to the buried layer 104.

The capacitor 130 also includes a second deep doped region 132 implanted with n-type majority carrier dopants (e.g., phosphorus). The second deep doped region 132 surrounds the second trenches 131 and extends from the semiconductor surface layer 108 to the buried layer 104. In addition, the capacitor 130 includes a second polysilicon 136 with p-type majority carrier dopants (e.g., boron). The second polysilicon 136 extends inside the second dielectric liner 133, 134, 135 and fills the second trench 131 to the top side 103 of the semiconductor surface layer 108. The capacitor 130 also includes a shallow implant region 129 having majority carrier dopants of the second conductivity type. The shallow implant region 129 extends in the semiconductor surface layer 108 between the second trenches 131 within the second deep doped region 132.

The semiconductor device 100 includes a metallization structure that extends over the semiconductor surface layer 108. The metallization structure includes conductive features that connect the first polysilicon 126 to the first deep doped region 122 for the trench-based isolation structures 120, as well as second conductive features connected to the second polysilicon 136 to form a first capacitor plate, and further conductive features connected to the second deep doped region 132 to form a second capacitor plate of the capacitor 130. The metallization structure includes a first dielectric structure layer 154 formed over the semiconductor structure, and a multi-level upper metallization structure 156. In one example, the first dielectric 154 structure layer is a pre-metal dielectric (PMD) layer disposed over the transistors 101 and the upper surface of the semiconductor structure. In one example, the first dielectric structure layer 154 includes silicon dioxide (SiO₂) deposited over the transistors 101, the semiconductor surface layer 108 and the STI structures 118. The metallization structure 154, 156 covers the transistors 101 and provides internal and/or external electrical interconnection to the transistor source, drain and gate terminals.

The PMD layer 154 includes contact structures 160 (e.g., tungsten) that provide direct electrical connection (e.g., direct contact or connection through a silicide layer such as CoSi₂, not shown) to one or more features of the transistors 101. The PMD material layer 154 is formed over the illustrated structure, with contact structures 160 formed therein to provide electrical interconnection access for one or more further upper metallization layers 158 and 164-168. In one example, a silicide is formed over the top surfaces of the source, drain and gate electrode structures of the transistors 101, and over the tops of the polysilicon features 126, 136 and to the deep doped regions 122, 132. Contacts 160 of the PMD layer 154 are connected to the polysilicon features 126, 136 and to the deep doped regions 122, 132 of the isolation structure 120 and the capacitor 130.

The upper metallization structure 156 includes one or more layers. In the illustrated example, the upper metallization structure 156 includes a first metallization layer 158 formed over the PMD layer 154, as well as further metallization layers 164, 165, 166, 167, and 168 progressively formed over the preceding layer as shown in FIG. 1. The device 100 in FIGS. 1 and 2 is shown as a wafer 170 prior to singulation and packaging, but the illustrated structure represents the described features after separated as a die for packaging. Although the example die 170 is an integrated circuit with multiple components, such as transistors 101, other stand-alone discrete semiconductor device implementations can include a single transistor or other electronic component with an isolation structure 120 and at least one capacitor 130.

The upper metallization structure 156 is a 6 layer with a first layer 158, referred to herein as an interlayer or interlevel dielectric (ILD) layer. Different numbers of layers can be used in different implementations. In one example, the first ILD layer 158, and the other ILD layers of the upper metallization structure 156 are formed of silicon dioxide (SiO₂) or other suitable dielectric material. In certain implementations, the individual layers of the multi-layer upper metallization structure 156 are formed in two stages, including an intra-metal dielectric (IMD, not shown) sub layer with conductive metal routing features or lines 162 (e.g., aluminum, copper, etc.), and an ILD sublayer overlying the IMD sub layer with conductive contacts or plugs 163 (e.g., tungsten vias). The individual IMD and ILD sublayers can be formed of any suitable dielectric material or materials, such as SiO₂-based dielectric materials. The first layer 158, and the subsequent layers in the upper metallization structure 156 include conductive metallization interconnect structures 162, referred to as lines, formed on the top surface of the underlying layer. In this example, the first layer 158 and the subsequent ILD layers also include conductive vias 163, such as tungsten or aluminum that provide electrical connection from the metallization features 162 of an individual layer to an overlying metallization layer.

The example of FIG. 1 includes a second layer 164 disposed over the first layer 158. The ILD layer 158 includes conductive interconnect structures 162 and vias 163. The structures 162, 163 can be the same metal or different metals in various implementations. The individual layers can be constructed using any suitable metallization fabrication processing, such as single damascene or dual damascene processes. The illustrated structure includes further metallization levels with corresponding dielectric layers 165, 166 and 167, as well as an uppermost or top metallization layer 168. The individual layers 165-168 in this example include conductive interconnect structures 162 and associated vias or contact plugs 163.

The semiconductor structure, the electronic components (e.g., the transistors 101), the capacitor 130, the first dielectric structure layer 154 and the upper metallization structure 156 form a wafer or die 170 with an upper side or surface 171. The upper side 171 of the metallization structure 156 forms an upper side of the wafer or die 170. The top metallization layer 168 includes conductive features 169, such as upper most aluminum vias. The conductive features 169 include a side or surface at the upper side 171 of the wafer or die 170 at the top of the uppermost metallization layer 168. Any number of conductive features 169 may be provided. One or more of the conductive features 169 can be electrically coupled with an electronic component such as one of the transistors 101.

The upper ILD dielectric layer 168 in one example is covered by one or more passivation layers 173 (e.g., protective overcoat (PO) and/or passivation layers), for example, silicon nitride (SiN), silicon oxynitride (SiOₓN_{y}), or silicon dioxide (SiO₂). In one example, the passivation layer or layers 173 include one or more openings that expose a portion of the conductive features 169 to allow electrical connection of the features 169 to corresponding contact structures 174. The contact structures 174 extend outward (e.g., upward along the “Z” direction in FIG. 1) from the upper side 171 of the metallization structure 156. The individual contact structures 174 in one example include a conductive seed layer, such as copper that extends outward from the upper side 171 of the metallization structure 156. In one example, the contact structure 174 includes titanium (Ti) or titanium tungsten (TiW).

The metallization structure 154, 156 includes first conductive features 160, 162 of the metallization structure 154, 156 that connect the first polysilicon 126 to the first deep doped region 122. This provides an isolation trench structure 120 that electrically isolates the active region 110 of the semiconductor structure from the capacitor 130 and from other regions of the wafer or die 170. In addition, the metallization structure includes second conductive features 160, 162 that are connected to the second polysilicon 136 to form a first capacitor plate, as well as further conductive features 160, 162 that are connected to the second deep doped region 132 to form a second capacitor plate. The metallization structure 154, 156 allows for further conductive connections (not shown) to connect the first and second capacitor plates to other circuitry within the wafer or die 170, and/or to provide external connection for one or both of the first and second capacitor plates.

FIG. 2 shows a top view of a portion of the device 100. In the illustrated example, the isolation structure 120 extends around the lateral periphery of the active region 110, and also extends around three sides of a capacitor region. In this example, the capacitor region includes an array 140 of multiple capacitor trenches 131, three of which are shown in the side view of FIG. 1. The trenches 131 are arranged in a hexagonal array in the illustrated example, though other arrangements are possible. In one example, the capacitor trench width 138 is approximately 1.2 μm, and a spacing distance between adjacent capacitor structures is approximately 0.6 μm. In one example, a shallow n-well implant (e.g., regions 129 in FIG. 1, not shown in FIG. 2) extends into the capacitor region by approximately 0.1 μm, and encloses the capacitor region by approximately 0.65 μm. In one example, the NBL 104 extends into the capacitor region as shown in FIG. 1. In another example (not shown) the capacitor region is enclosed by the NBL 104. In one example, a silicide block layer (not shown) extends beyond the capacitor region by approximately 0.25 μm, and extends into the capacitor region by approximately 0.255 μm.

Additional aspects of the device 100 are described in U.S. Pat. No. 10,811,543, which is incorporated herein by reference in its entirety.

In some baseline technology, the first trench 121 and the second trenches 131 may be formed using the so-called “Bosch process”. Briefly summarized, the Bosch process alternates between a relatively short first process condition that favors removal of substrate material (“etch sub-step”), and a relatively short second process condition that favors deposition of etch-resistant material (“deposition sub-step”) on sidewalls of the growing trench. One cycle of an etch sub-step followed by a deposition sub-step may remove a small amount of the etched semiconductor material, and forming a trench may include hundreds of cycles. A “baseline Bosch process” uses a same deposition sub-step time and a same etch sub-step time for the entire etch, from the surface of the substrate to the bottom of the intended trench. An example Bosch process may use a deposition sub-step time of 1.5 s and an etch sub-step time of 2.5 s, for a total cycle time of 4 s. A “dep/etch ratio” is defined as the deposition time in a sub-step divided by the etch time in a sub-step. For example, the described baseline Bosch has a dep/etch ratio of 0.6 (60%).

Trenches formed by the baseline Bosch process may reach a depth of 5-6 μm before a significant (e.g. 10%) difference in trench width results between the top of the trench (e.g. the top side 103) and the bottom of the trench. In some implementations it may be advantageous to form trenches with a greater depth, e.g. 20 μm or greater. One non-limiting example is now described.

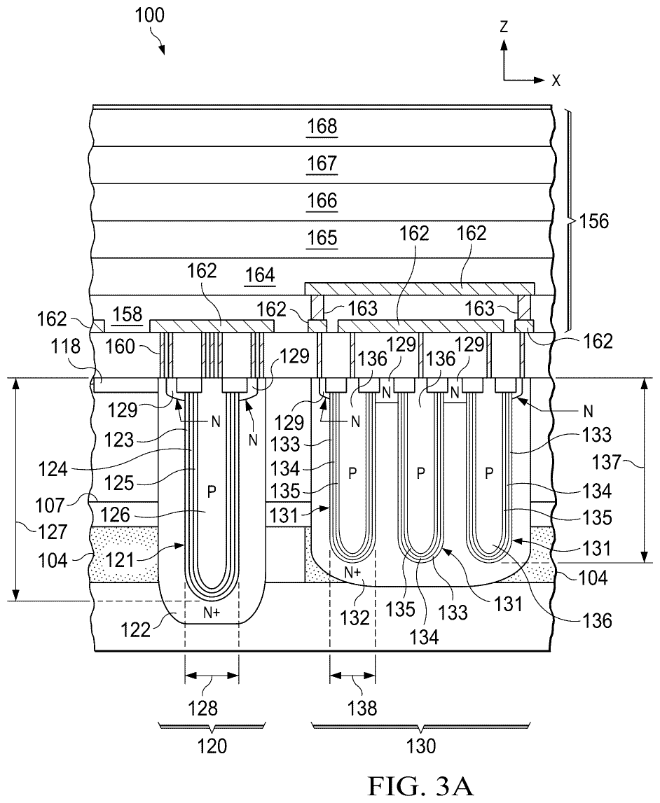

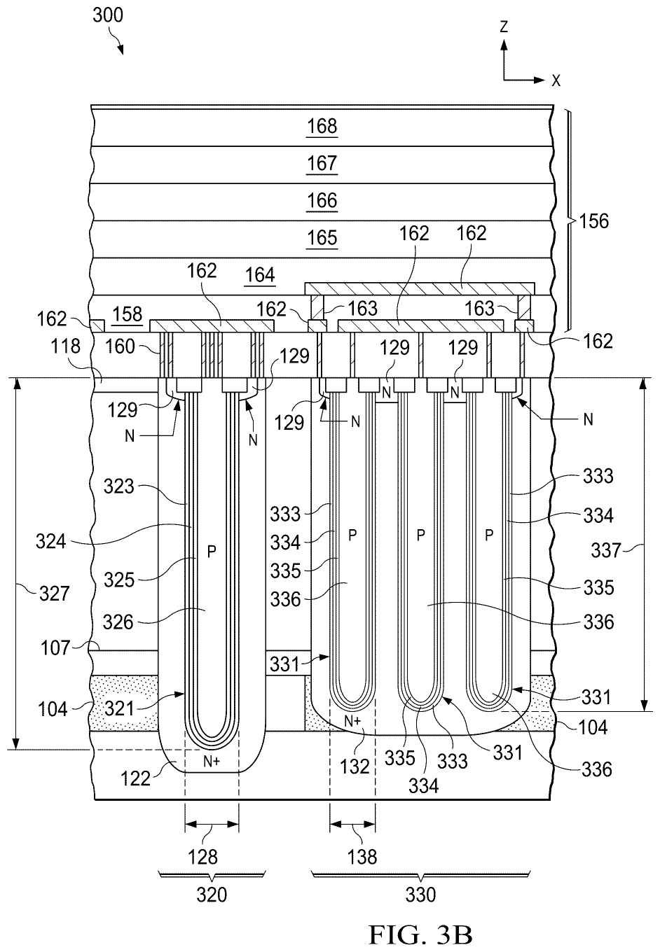

FIG. 3A illustrates a portion the device 100 of FIG. 1 including the trench 121 and the trenches 131. The capacitance of the capacitor 130 is in part a function of the depth 137 of the trenches 131. The capacitance per unit area (lateral area of the device 100) may be lower in cases in which the trenches 131 are deeper due to greater capacitive coupling between the polysilicon 136 and the deep doped region 132 for each trench 131. Thus the lateral area of the array 140 needed to produce a given capacitance may be reduced for deeper trenches 131. However the baseline Bosch process has been found to produce trenches with sidewall slope, or reduction of diameter with increasing depth, sufficient to cause subsequent material layers formed in the trench to pinch off or otherwise fail to fully extend into the trench when the trench is greater than about 10 μm for a round cylindrical trench target diameter of 2 μm. Thus the baseline Bosch process does not provide for deeper trenches that may allow the size of devices such as the capacitor 130 to be reduced.

FIG. 3B illustrates a portion of a device 300 that is an analog of the device 100 of FIG. 3A, and includes a trench-based isolation structure 320 and a deep-trench capacitor 330 in which trenches 321 and 331 have been formed according to examples of this disclosure. Other features of the device 300 that remain unchanged relative to the device 100 retain their feature indexes. The trench 321 has a greater first depth 327 than the first depth 127 of FIG. 3A, and the trench 331 has a greater second depth 337 than the second depth 137 of FIG. 3A. The first depth 327 may be at least 50% greater than the first depth 127 and the second depth 337 may be at least 50% greater than the second depth 137, or at least 10 μm. Some examples consistent with the description below may have a first depth 327 or second depth 337 of at least 20 μm, providing significant design flexibility. The greater depths is attributable to the improved processes for forming the trenches 321 and 331 as further described below. Other features of the device 300 are analogous to those of the device 100, with suitable modification to account for the greater depths of the trenches 321 and 331. So, for example, the device 300 includes dielectric layers 323, 324 and 325 analogous to the dielectric layers 123, 124 and 125, and dielectric layers 333, 334 and 335 analogous to the dielectric layers 133, 134 and 135.

An aspect ratio (AR) is defined as the depth of a trench divided by the top width or diameter, as applicable, at the top of the trench. The ability to form continuous, conformal dielectric layers in the trenches 321 and 331 depends in part on the aspect ratio, and in part on the difference between a bottom width or diameter at the bottom of the trench and the top width. In general, a trench or hole will have some amount of sidewall slope, resulting in the bottom width being smaller than the top width. If the bottom width is too small a subsequently-formed sidewall dielectric will pinch off the trench, resulting in a useable depth less than intended, and possibly inconsistent depths among trenches. As a general rule, a ratio of 80% between the bottom width and the top width, is expected to allow adequate conformity of the dielectric liners, with an aspect ratio of 10 or greater providing the ability to, e.g. form trench capacitors with a high capacitance per unit area.

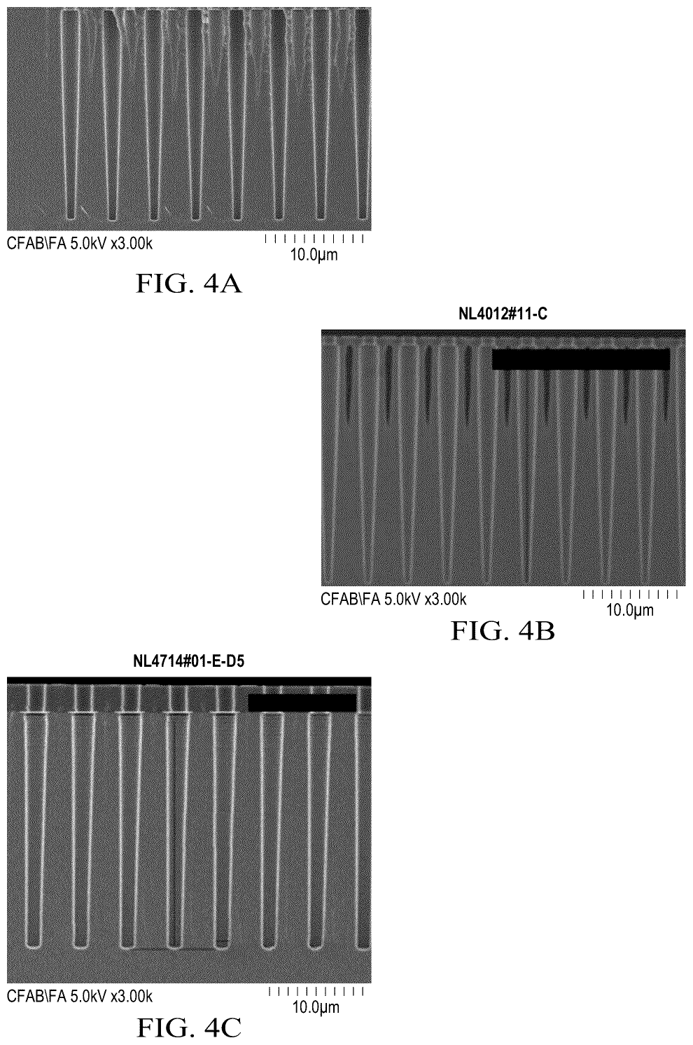

FIGS. 4A-4C illustrate examples of circular trenches having a depth greater than 20 μm in a silicon substrate formed using a baseline Bosch process with different dep/etch ratios, each example having a same dep/etch ratio from top to bottom. In all three examples, round trenches were formed using 2 μm diameter hole pattern, 50 mtorr (6.7 Pa) pressure and 800 W RF power. A deposition step used −90 V bias voltage, 100 sccm C₄F₈. An etch step used −300 V bias voltage and 100 sccm SF₆. A constant dep/etch ratio was used, but a different dep/etch ratio was used in each example. In FIG. 4A, the holes have a depth of about 23 μm, and in FIGS. 4B and 4C the holes have a depth of about 26 μm. Qualitatively, the holes in FIGS. 4A and 4B have clearly visible sidewall slope, or narrowing toward the bottom, while the holes in FIG. 4C are relatively straight. The holes in FIG. 4C have a bottom diameter of about 1.56 μm, and a top diameter of about 2.4 μm, for a ratio of 65%. Recalling that dielectric liners 133, 134 and 135 are formed within the trenches 131 before being filled with the polysilicon 136, this ratio is not considered sufficient to reliably fill deep trenches, e.g. those having a depth of at least 20 μm.

Without implied limitation by theory, it is understood that the narrowing the round trenches exemplified by FIGS. 4A-4C results from insufficient inflow of reactant gases and/or insufficient outflow of byproduct gases during the deposition and etch sub-steps of the baseline Bosch process. Residual etch byproducts in the trenches are thought to inhibit the sidewall deposition portion and/or etch portion of the Bosch process. While the inflow/outflow may be sufficient at relatively shallow depths, e.g. less than 10 μm for holes having a nominal diameter of 2 μm, this phenomenon may generally manifest at a depth that results in a sufficiently high aspect ratio (depth/diameter), e.g. greater than 5-6.

Examples of the disclosure include the realization that as the depth of the trench increase, additional time may be provided to the dep sub-step and to the etch sub-step, thus allowing greater penetration of reactant gases into the trench and greater exhaust of byproduct gases from the trench. Improved etch processes that result in a greater ratio of bottom diameter to top diameter are thus provided by examples of the disclosure. In such improved processes, the trench etch may divided into several sections, with the cycle time being different in each section. In some examples the cycle time increases by at least 20% from a shallower section to a deeper section of the trench, and in some examples the cycle time increases by one second from a shallower section to a deeper section of the etch. In some examples the deposition portion of the etch increases by 40% from a shallower portion of the etch to a deeper portion of the etch, and the etch portion of the trench portion of the etch increases 60% from the shallower portion of the etch to the deeper portion of the trench.

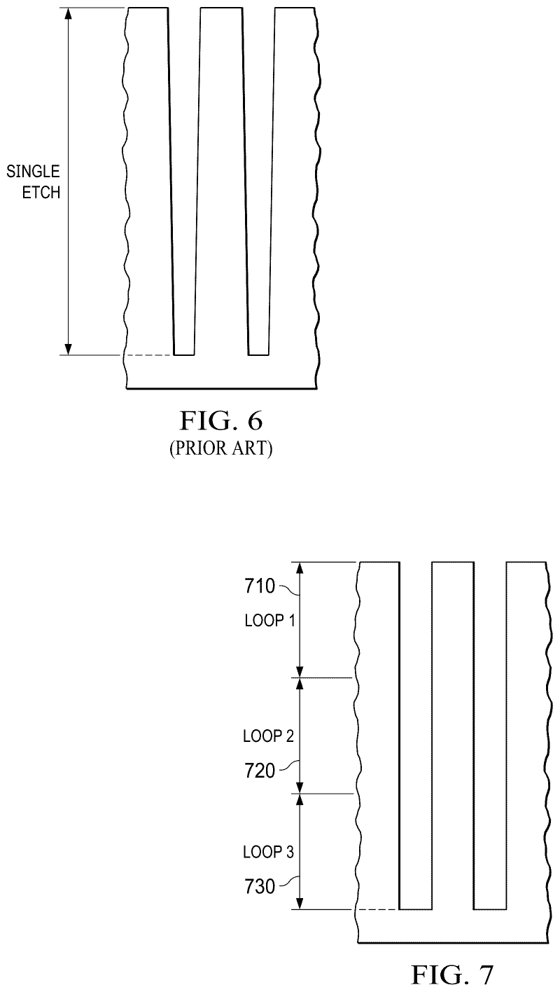

FIGS. 6 and 7 illustrate this aspect. FIG. 6 illustrates the conventional Bosch trench etch, in which the trench (hole) is formed using a single dep/etch cycle time from the top surface of the substrate to the bottom of the trench. As illustrated, the diameter of the trench decreases with increasing depth. FIG. 7 illustrates a trench (hole) formed according to examples of the disclosure. In a first, or shallowest etch loop 710, the deposition time has a first deposition time value T_{D1}, the etch time has a first etch time value T_{E1}, and there is a first dep/etch ratio R₁=T_{D1}/T_{E1}. In a second, deeper etch loop 720, the deposition time has a second deposition time value T_{D2}=T_{D1}+ΔT_{D1}, the etch time has a second etch time value T_{E2}=T_{E1}+ΔT_{E1}, and there is a second dep/etch ratio R₂=T_{D2}/T_{E2}. In a third, deeper etch loop 730, the deposition time has a third deposition time value T_{D3}=T_{D2}+ΔT_{D2}, the etch time has a second etch time value T_{E3}=T_{E2}+ΔT_{E2}, and there is a third dep/etch ratio R₃=T_{D3}/T_{E3}. The first, second and third dep/etch rations may be the same or different. The total etch time at each of the etch loops 710, 720 and 730 is determined by the number of cycles (repetitions) of the particular deposition, and need not be equal for each of the etch loops 710, 720 and 730. Moreover, examples consistent with the disclosure may form the trenches or holes using any number of etch portions greater than one.

FIGS., 5A-5C illustrate examples of circular trenches formed in a silicon substrate and having a height at least 20 μm. The trenches were patterned using a mask with 2 μm diameter openings, using a reactor chamber with 50 mtorr (6.7 Pa) pressure and 800 W RF power. All deposition sub-steps used −90 V bias voltage, 100 sccm C₄F₈ and 1 sccm SF₆. All etch sub-steps used −300 V bias voltage, 100 sccm SF₆ and 1 sccm C₄F₈. A flow rate of 1 sccm of SF₆ or C₄F₈ is considered “essentially no flow” of either source gas and may be implemented to maintain the process tool mass flow controller in a ready state. A first etch loop included 100 dep/etch cycles, with a deposition sub-step time of 1.5 s and an etch sub-step time of 2.5 s, for a cycle time of 4 s and a dep/etch ratio of 0.6. The incremental depth of this first loop is expected to be about 12 μm. A second etch loop included 100 dep/etch cycles, with a deposition sub-step time of 1.9 s and an etch sub-step time of 3.1 s for a cycle time of 5 s and a dep/etch ratio of 0.6. The incremental depth of this second loop is expected to be about 9 μm. A third etch loop included 70 dep/etch cycles, with a deposition sub-step time of 2.3 s and an etch sub-step time of 3.7 s for a cycle time of 6 s and a dep/etch ratio of 0.6. The incremental depth of this first loop is expected to be about 6 μm, for a total of 27 μm.

The increase of cycle time from the first etch loop to the second etch loop was 1 s, or 25%, and the increase of cycle time from the second etch loop to the third etch loop was 1 s, or 20%. The increase of time of the deposition sub-step in the second etch loop relative to the first etch loop was about 27%, and the increase of time of the deposition sub-step in the third etch loop relative to the second etch loop was about 21%. The increase of time of the etch sub-step in the second etch loop relative to the first etch loop was about 24%, and the increase of time of the etch sub-step in the third etch loop relative to the second etch loop was about 19%.

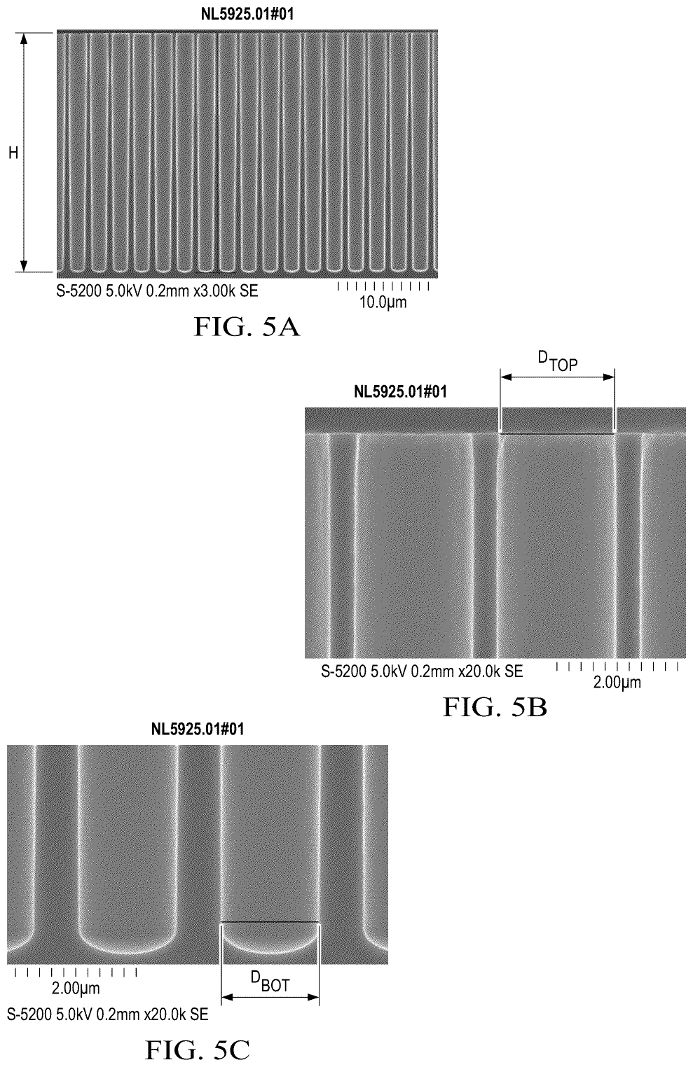

FIG. 5A shows the substrate at a magnification providing a view of the trenches from the substrate surface to the trench bottoms. Qualitatively the trenches appear to have relatively little slope and approximately square bottoms. Measurement of FIG. 5A shows a height H of about 26.9 μm. FIG. 5B shows the substrate at a magnification providing a view of the trench tops. Measurement of FIG. 5B shows a diameter D_{TOP} of about 1.93 μm. FIG. 5C shows the substrate at a magnification providing a view of the trench bottoms, clearly showing the trench bottoms are well-formed. Measurement of FIG. 5C shows a diameter D_{BOT} of about 1.66 μm, resulting in a ratio of 0.86 (86%) of the bottom diameter D_{BOT} as compared to the top diameter D_{TOP} for an aspect ratio of at least 10.

The conditions used to produce the example trenches of FIGS. 5A-5C are specific conditions in a range of conditions expected to provide acceptable round or linear trenches having a diameter or width of about 2 μm and a depth of at least 20 μm. In other implementations different conditions may be used to achieve the described trench characteristics In some examples the process pressure may be in a range from 30 mtorr (4 Pa) to 70 mtorr (9.3 Pa); the process RF power may range from 600 W to 900 W; the deposition sub-step substrate bias may range from −50 V to −150 V; and the etch sub-step substrate bias may range from −150 V to −350 V. During any deposition sub-step the C₄F₈ flow rate may be 50 sccm to 200 sccm, with the SF₆ flow rate essentially zero, e.g. 1 sccm. In some examples C₅F₈ may be used in lieu of C₄F₈ with suitable process modification. During any etch sub-step the SF₆ flow rate may be 50 sccm to 200 sccm, with the C₄F₈ flow rate essentially zero, e.g. 1 sccm. In a first etch loop, the deposition sub-step time may be in a range from about 1.2 s to about 1.8 s, and the etch sub-step time may be in a range from about 2.0 s to about 3.0 s. In a second etch loop, the deposition sub-step time may be at least 10% greater than the deposition sub-step time of the first etch loop, and the etch sub-step time may be at least 10% greater than the etch sub-step time of the first etch loop. In the second etch loop, the deposition sub-step time may be in a range from about 1.5 s to about 2.3 s, and the etch sub-step time may be in a range from about 2.5 s to about 3.8 s. Should a third etch loop be desired, the deposition sub-step time may be at least 10% greater than the deposition sub-step time of the second etch loop, and the etch sub-step time may be at least 10% greater than the etch sub-step time of the second etch loop. The deposition sub-step time may be in a range from about 1.8 s to about 2.7 s, and the etch sub-step time may be in a range from about 3.0 s to about 4.5 s. Finally, the dep/etch ratio may be in a range from 0.4 to 0.8 (40% to 80%).

Note that the specific conditions for a selected trench width or diameter and a selected trench depth may be determined empirically for the selected trench characteristics. In general it is expected that, keeping other process parameters unchanged, the dep/etch ratio will decrease slightly with increasing process pressure, remain about the same for change of RF power or substrate bias voltage, decrease for lower C₄F₈ flow rate and increase for greater SF₆ flow rate.

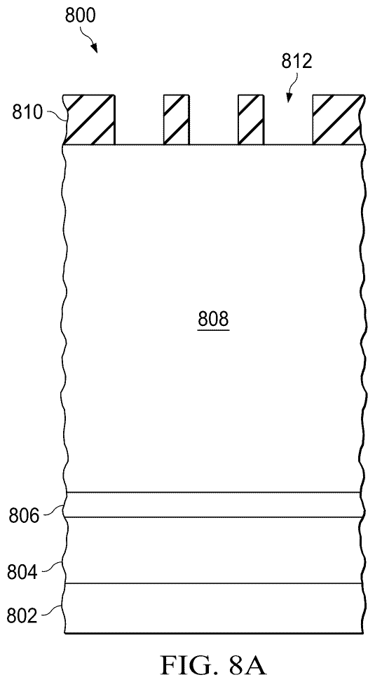

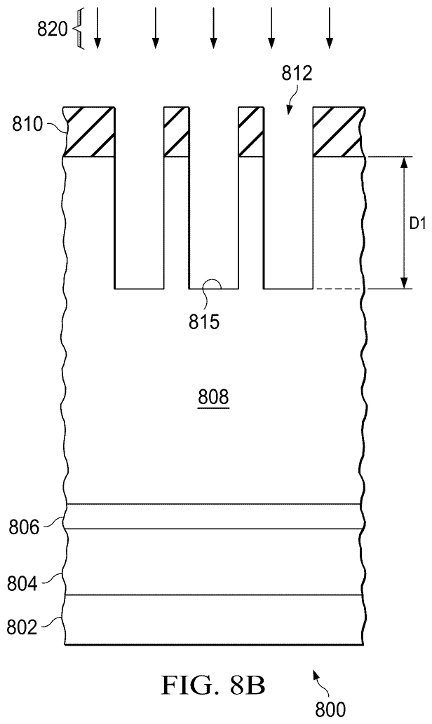

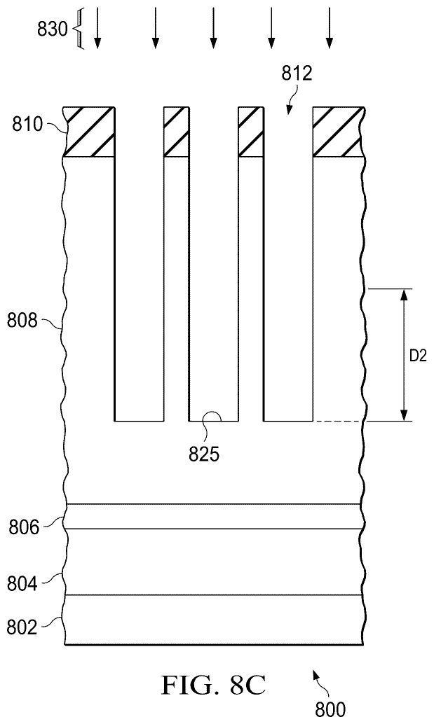

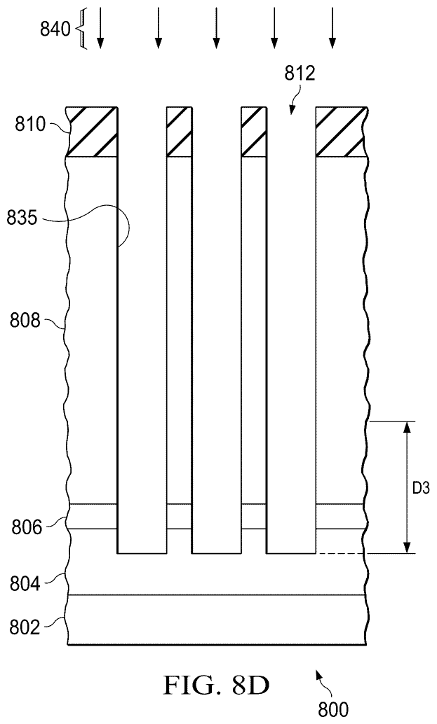

FIGS. 8A-8D illustrate a process of forming a deep linear or round trench in a device 800 according to various examples. In FIG. 8A a semiconductor layer 808 has been formed over a substrate 802. The semiconductor layer 808 may be a lightly-doped epitaxial (epi) layer having a first conductivity type, e.g. p-type. A buried layer 804 having an opposite second conductivity type, e.g. n-type, has been formed between the semiconductor layer 808 and the substrate 802. A buried layer 806 having the first conductivity type has been formed between the semiconductor layer 808 and the buried layer 804. The layers 804, 806 and 808 may be formed by a known or future-developed process or processes. A resist or hardmask layer 810 has been formed over the semiconductor layer 808. The resist or hardmask layer 810 includes multiple openings 812 corresponding to linear or circular cylindrical trenches to be formed extending from a top surface of the semiconductor layer 808 toward the substrate 802.

FIG. 8B illustrates the device 800 during formation of partial trenches 815. A formation process loop 820 includes multiple etch sub-steps alternating with multiple deposition sub-steps, e.g. as described in various examples. The formation process loop 820 may include 100 cycles of alternating deposition sub-steps of 1.5 s and etch sub-steps of 2.5 s. After completion of the formation process loop 820, the partial trenches 815 have a depth D₁, which may be about 12 μm for examples in which the openings 812 define circles with 2 μm diameter.

FIG. 8C illustrates the device 800 during formation of partial trenches 825. A formation process loop 830 includes multiple etch sub-steps alternating with multiple deposition sub-steps, e.g. as described in various examples. The formation process loop 820 may include 100 cycles of alternating deposition sub-steps of 1.9 s and etch sub-steps of 3.1 s. After completion of the formation process loop 830, the partial trenches 825 have a depth D₂, which may be about 20-21 μm for examples in which the openings 812 define circles with 2 μm diameter.

FIG. 8D illustrates the device 800 during formation of complete trenches 835. A formation process loop 840 includes multiple etch sub-steps alternating with multiple deposition sub-steps, e.g. as described in various examples. The formation process loop 840 may include 70 cycles of alternating deposition sub-steps of 2.3 s and etch sub-steps of 3.7 s. After completion of the formation process loop 840, the complete trenches 835 have a depth D₃, which may be about 27 μm for examples in which the openings 812 define circles with 2 μm diameter. The complete trenches 835 have a top diameter and a bottom diameter, a ratio of the bottom diameter to the top diameter being at least 80%.

While examples of the disclosure have been described primarily in the context of forming deep cylindrical trenches in a silicon substrate for forming a deep trench capacitor, the principles of the illustrated examples may be beneficially applied in other contexts such as trench FETs and MEMS devices. Other modifications are also possible in the described embodiments, and other embodiments are possible, within the scope of the claims.

We claim:

1. A method of forming an integrated circuit, comprising:
forming a plurality of openings in a resist layer over a semiconductor substrate;
removing portions of a semiconductor surface layer exposed by the openings, thereby forming a plurality of deep trenches, the removing including:
performing a first etch loop including a first plurality of repetitions, the first etch loop including a deposition process executed for a first deposition time and an etch process executed for a first etch time; and
performing a second etch loop including a second plurality of repetitions, the second etch loop including the deposition process executed for a second deposition time and an etch process executed for a second etch time, the second deposition time at least 10% greater than the first deposition time and the second etch time at least 10% greater than the first etch time.

2. The method according to claim 1, wherein the removing further comprises performing a third etch loop including a third plurality of repetitions, the third etch loop including the deposition process executed for a third deposition time and an etch process executed for a third etch time, the third deposition time at least 10% greater than the second deposition time and the third etch time at least 10% greater than the third etch time.

3. The method according to claim 1, wherein the second deposition time is about 25% greater than the first deposition time and the second etch time is about 25% greater than the first etch time.

4. The method according to claim 2, wherein:
the second deposition time is about 25% greater than the first deposition time and the second etch time is about 25% greater than the first etch time; and
the third deposition time is about 20% greater than the second deposition time and the third etch time is about 20% greater than the first etch time.

5. The method according to claim 1, wherein the deep trenches are round trenches with a diameter of about 2 μm or less at a top surface of the surface layer.

6. The method according to claim 1, wherein the deep trenches are round trenches with a depth of at least about 20 μm, a diameter of the deep trenches at a bottom of the trenches is at least about 75% of a diameter of the deep trenches at a top surface of the surface layer.

7. The method according to claim 1, the deposition process includes flowing C₄F₈ into a reactor chamber with essentially no SF₆, and the etch process includes flowing SF₆ into the reactor chamber with essentially no C₄F₈.

8. The method according to claim 1, further comprising filling the deep trenches with polysilicon.

9. The method according to claim 1, wherein the first deposition time is about 1.5 s, the first etch time is about 2.5 s, the second deposition time is about 1.9 s, the second etch time is about 3.1 s, and the first and second pluralities are about 100.

10. The method according to claim 9, wherein the first etch loop removes a first depth of substrate material and the second etch loop removes a second depth of semiconductor material about 30% less than the first depth.

11. A semiconductor device, comprising:
a semiconductor surface layer having a first conductivity type over a substrate;
a buried layer having an opposite second conductivity type within the semiconductor surface layer; and
a trench extending from a top surface of the semiconductor surface layer into the buried layer, the trench having a depth of at least 20 μm, an aspect ratio of at least 10:1, and a bottom diameter at a trench bottom at least about 75% of a top diameter at the top surface.

12. The semiconductor device of claim 11, wherein the trench is one of a plurality of deep trenches extending from the top surface to the buried layer, each of the deep trenches filled with one of a corresponding plurality of doped polysilicon electrodes.

13. The semiconductor device of claim 12, wherein the plurality of doped polysilicon electrodes extend through a doped layer having the second conductivity type.

14. The semiconductor device of claim 13, wherein the plurality of doped polysilicon electrodes are configured as a first electrode of a capacitor and the doped layer is configured as a second electrode of the capacitor.

15. The semiconductor device of claim 11, wherein the trench has a circular cross-section at the top surface with a diameter of about 2 μm between the top surface and the trench bottom.

16. The semiconductor device of claim 14, further comprising a transistor having a terminal connected to the first electrode or the second electrode.

17. The semiconductor device of claim 11, wherein the bottom diameter is at least about 85% of the top diameter.

18. The semiconductor device of claim 11, wherein the semiconductor surface layer comprises an epitaxial silicon layer.

19. The semiconductor device of claim 11, wherein the first conductivity type is P-type and the second conductivity type is N-type.

20. The semiconductor device of claim 12, wherein the plurality of deep trenches are arranged in a hexagonal array.
